(19) United States
(12) Patent Application Publication
(10) Pub. No.: US 2023/0384977 A1
(43) Pub. Date: Nov. 30, 2023

(54) MEMORY SYSTEM FOR CONTROLLING OPERATING SPEED AND DATA PROCESSING SYSTEM INCLUDING THE SAME

(71) Applicant: SK hynix Inc., Gyeonggi-do (KR)

(72) Inventor: Youn Won PARK, Gyeonggi-do (KR)

(21) Appl. No.: 17/981,653

(22) Filed: Nov. 7, 2022

(30) Foreign Application Priority Data
May 27, 2022 (KR) 10-2022-0065531

(51) Int. Cl. G06F 3/06

(52) U.S. Cl. CPC G06F 3/0659; G06F 3/0634; G06F 3/0619; G06F 3/0679

(57) ABSTRACT

A memory system comprising: a memory device configured to store, in a non-volatile storage area included therein, a list of a plurality of performance classes and a table of performance information representing a group of performance parameter values for each of the plurality of performance classes, and a controller configured to provide the list to an external device according to a first request received from the external device, select one of the plurality of performance classes within the table according to a second request received from the external device, and control an operation of the memory device at an operation speed and in an operation method according to the performance parameter values corresponding to the selected performance class.

### CROSS-REFERENCE TO RELATED APPLICATION

This application claims priority under 35 U.S.C. § 119 to Korean Patent Application No. 10-2022-0065531 filed on May 27, 2022, which is incorporated herein by reference in its entirety.

### BACKGROUND

### 1. Field

Various embodiments of the present disclosure relate to a memory system, and particularly, to a memory system for controlling an operating speed and a data processing system including the same.

### 2. Discussion of the Related Art

Recently, a computer environment paradigm has shifted to ubiquitous computing, which enables a computer system to be accessed anytime and everywhere. As a result, the use of portable electronic devices such as mobile phones, digital cameras, notebook computers and the like has increased, Such portable electronic devices typically use or include a memory system that uses or embeds at least one memory device, i.e., a data storage device. The data storage device can be used as a main storage device or an auxiliary storage device of a portable electronic device.

In a computing device, unlike a hard disk, a data storage device implemented as a nonvolatile semiconductor memory device is advantageous in that it has excellent stability and durability because it has no mechanical driving part (e.g., a mechanical arm), and has high data access speed and low power consumption. Examples of such a data storage device include a universal serial bus (USB) memory device, a memory card having various interfaces, and a solid state drive (SSD).

### SUMMARY

Various embodiments of the present disclosure are directed to providing a memory system, which is produced with performance information for controlling an operating speed stored therein and is mounted to control the operating speed through association with a host, and a data processing system including the same.

Technical concerns to be achieved in the present disclosure are not limited to the aforementioned technical concerns and the other unmentioned technical concerns will be clearly understood by those skilled in the art to which the present disclosure pertains from the following description.

In an aspect of an embodiment of the present disclosure, a memory system may include: a memory device configured to store, in a non-volatile storage area included therein, a list of a plurality of performance classes and a table of performance information representing a group of performance parameter values for each of the plurality of performance classes; and a controller configured to provide the list to an external device according to a first request received from the external device, select one of the plurality of performance classes within the table according to a second request received from the external device, and control an operation of the memory device at an operation speed and in an operation method according to the performance parameter values corresponding to the selected performance class.

In an aspect of an embodiment of the present disclosure, a memory system may include: a memory device configured to store, in a non-volatile storage area, a list of a plurality of performance classes and a table of performance information representing a group of performance parameter values for each of the plurality of performance classes; and a controller configured to provide the list to an external device in an entry section of a set operation mode, select one of the plurality of performance classes within the table according to a request received from the external device, and control an operation of the memory device at an operation speed and in an operation method according to the performance parameter values corresponding to the selected performance class in an escape section of the set operation mode.

In an aspect of an embodiment of the present disclosure, a data processing system may include: an external device configured to request a user to select one of a plurality of performance classes within a received list; and a memory system configured to store, in a nonvolatile memory area, the list and a table of performance information representing a group of performance parameter values for each of the plurality of performance classes, transmit the list to the external device, select one of the plurality of performance classes within the table according to the selected performance class, and operate at an operation speed and in an operation method according to the performance parameter values corresponding to the selected performance class.

In an aspect of an embodiment of the present disclosure, a method for operating a data processing system including a memory system including a memory device including a non-volatile storage area and an external device for controlling an operation of the memory system at a request of a user, the method may include: a test operation of generating a list of a plurality of performance classes through a test and a table of performance information representing a group of performance parameter values for each of the plurality of performance classes to store the list and the table in the non-volatile storage area; a list transmission operation of providing the list stored in the memory system to the external device after the test operation; a selection request operation in which the external device requests a user to select one of the plurality of performance classes within the list after the list transmission operation; a class selection operation in which the memory system selects one of the plurality of performance classes within the table according to the performance class selected by the user; and an operation control operation in which the memory system controls an operation of the memory device at an operation speed and in an operation method according to the performance parameter values corresponding to the selected performance class.

In an aspect of an embodiment of the present disclosure, an operating method of a host and a memory system, the operating method may include: providing, by the memory system, the host with information of one or more performance classes; selecting, by the host, one of the performance classes; and adjusting, by the memory system, performance thereof according to one or more performance parameter values corresponding to the selected performance class.

The present technology may store performance information for adjusting an operating speed determined through a test in a nonvolatile memory area inside a memory system, provide a host with a list of options related to operating speed control of the memory system during mounting, and adjust the operating speed of the memory system according to the selection of the host based on the list of options.

Consequently, the present technology may control the operating speed of the memory system in an optimized form so that life expectancy is not reduced.

### BRIEF DESCRIPTION OF THE DRAWINGS

FIG. 1 is a diagram for describing a data processing system including a memory system according to an embodiment of the present disclosure.

FIG. 2 is a diagram for describing operations of components included in the memory system illustrated in FIG. 1 according to an embodiment of the present disclosure,

FIG. 3 to FIG. 5 are flowcharts for describing an operation of the memory system according to an embodiment of the present disclosure illustrated in FIG. 1 and FIG. 2.

FIG. 6 is a diagram for describing an example of a list and performance information described with reference to FIG. 1 and FIG. 2 according to an embodiment of the present disclosure.

### DETAILED DESCRIPTION

Various embodiments of the present disclosure are described below with reference to the accompanying drawings. Elements and features of this disclosure, however, may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. The terms in a claim do not foreclose the apparatus from including additional components (e.g., an interface unit, circuitry, etc.).

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational (e.g., is not turned on nor activated), The block/unit/circuit/component used with the “configured to” language includes hardware—for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in a manner that is capable of performing the task(s) at issue. “Configured to” may also include adapting a manufacturing process (e.g., a semiconductor fabrication facility) to fabricate devices (e.g., integrated circuits) that implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or a portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that the terms precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. For example, the phrase “determine A based on B.” While in this case, B is a factor that affects the determination of A, such a phrase does not foreclose the determination of A from also being based on C. In other instances, A may be determined based solely on B.

Herein, an item of data, a data item, a data entry or an entry of data may be a sequence of bits. For example, the data item may include the contents of a file, a portion of the file, a page in memory, an object in an object-oriented program, a digital message, a digital scanned image, a part of a video or audio signal, metadata or any other entity which can be represented by a sequence of bits. According to an embodiment, the data item may include a discrete object. According to another embodiment, the data item may include a unit of information within a transmission packet between two different components.

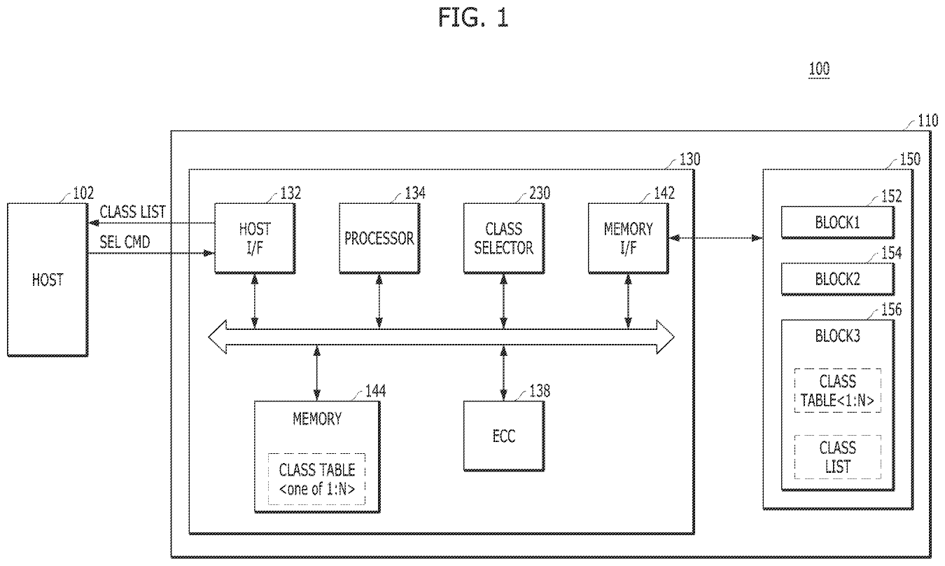

FIG. 1 is a diagram for describing a data processing system including a memory system according to an embodiment of the present disclosure.

Referring to FIG. 1, the data processing system 100 may include a host 102 engaged or operably coupled with the memory system 110.

The host 102 may include any of a portable electronic device, such as a mobile phone, an MP3 player, a laptop computer, or the like, and an electronic device, such as a desktop computer, a game player, a television (TV), a projector, or the like.

The host 102 also includes at least one operating system (OS), which can generally manage and control, functions and operations performed in the host 102. The OS can provide interoperability between the host 102 engaged with the memory system 110 and the user using the memory system 110. The OS may support functions and operations corresponding to a user's requests. By way of example but not limitation, the OS can be classified into a general operating system and a mobile operating system according to mobility of the host 102. The general operating system may be split into a personal operating system and an enterprise operating system according to system requirements or a user's environment. The personal operating system, including Windows and Chrome, may be subject to support services for general purposes. But the enterprise operating systems can be specialized for securing and supporting high performance, including Windows servers, Linux, Unix, and the like. Further, the mobile operating system may include Android, iOS, Windows mobile, and the like. The mobile operating system may be subject to support services or functions for mobility (e.g., a power saving function). The host 102 may include a plurality of operating systems. The host 102 may execute multiple operating systems interlocked with the memory system 110, corresponding to a user's request. The host 102 may transmit a plurality of commands corresponding to the user's requests into the memory system 110, thereby performing operations corresponding to commands within the memory system 110. In summary, the host 102 may mean all external devices for controlling the operation of the memory system 110 outside the memory system 110.

The memory system 110 operates in response to a request of the host 102, and, in particular, stores data to be accessed by the host 102. The memory system 110 may be used as a main memory device or an auxiliary memory device of the host 102. The memory system 110 may be implemented as one of various types of storage devices, depending on a host interface protocol which is coupled with the host 102. For example, the memory system 110 may be implemented as any of a solid state driver (SSD), a multimedia card (e.g., an MMC, an embedded MMC (eMMC), a reduced size MMC (RS-MMC) and a micro-MMC), a secure digital card (e.g., an SD, a mini-SD and a micro-SD), a universal serial bus (USB) storage device, a universal flash storage (UFS) device, a compact flash (CF) card, a smart media card, and a memory stick. The components included in the controller 130 may be added or removed according to an implementation form of the memory system 110.

The storage devices for the memory system 110 may be implemented with a volatile memory device, for example, a dynamic random access memory (DRAM) and a static RAM (SRAM), and/or a nonvolatile memory device such as a read only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magneto-resistive RAM (MRAM), a resistive RAM (RRAM or ReRAM), and a flash memory.

The memory system 110 may include a controller 130 and a memory device 150. The memory device 150 may store data to be accessed by the host 102. The controller 130 may control an operation of storing data in the memory device 150.

The controller 130 and the memory device 150 included in the memory system 110 may be integrated into a single semiconductor device, which may be included in any of the various types of memory systems as discussed above in the examples.

By way of example but not limitation, the controller 130 and memory device 150 may be implemented with an SSD. When the memory system 110 is used as an SSD, the operating speed of the host 102 connected to the memory system 110 can be improved more than that of the host 102 implemented with a hard disk. In addition, the controller 130 and the memory device 150 may be integrated into one semiconductor device to form a memory card, such as a PC card (PCMCIA), a compact flash card (CF), a memory card such as a smart media card (SM, SMC), a memory stick, a multimedia card (MMC, RS-MMC, MMCmicro), a SD card (SD, miniSD, microSD, SDHC), a universal flash memory, or the like.

The memory system 110 may be configured as a part of, for example, a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation system, a black box, a digital camera, a digital multimedia broadcasting (DMB) player, a 3-dimensional (3D) television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, a radio frequency identification (RFID) device, or one of various components configuring a computing system.

The controller 130 in the memory system 110 may control the memory device 150 in response to a request from the host 102. For example, the controller 130 may provide data read from the memory device 150, to the host 102, and may store data provided from the host 102, in the memory device 150. To this end, the controller 130 may control read, write, program, and erase operations of the memory device 150.

According to an embodiment, when a write request is inputted from the host 102, the controller 130 may receive, from the host 102, write data to be stored in the memory device 150 and a logical address (LA) for identifying the write data. The controller 130 may convert the inputted logical address into a physical address (PA) indicating physical addresses of memory cells in which the write data are to be stored among the memory cells included in the memory device 150. For example, one physical address may correspond to one physical page. The controller 130 may provide the memory device 150 with a write command for storing data, a physical address, and write data.

According to another embodiment, when a read request is inputted from the host 102, the controller 130 may receive a logical address corresponding to the read request from the host 102. The logical address corresponding to the read request may be a logical address for identifying read-requested data. The controller 130 may acquire a physical address mapped with the logical address corresponding to the read request from map data indicating the corresponding relationship between the logical address provided by the host 102 and the physical address of the memory device 150. Then, the controller 130 may provide a read command and the physical address to the memory device 150.

In an embodiment, during an erase operation, the controller 130 may provide an erase command and a physical block address to the memory device 150.

In an embodiment, the controller 130 may autonomously generate a command, an address, and data regardless of a request from the host 102, and may transmit the command, the address, and the data to the memory device 150, For example, the controller 130 may provide commands, addresses, and data to the memory device 150 to perform background operations, such as a program operation for wear leveling and a program operation for garbage collection.

The memory device 150 may be a nonvolatile memory device and may retain data stored therein even while electrical power is not supplied. The memory device 150 may store data provided by the host 102 through a write operation and provide data stored therein to the host 102 through a read operation.

In an embodiment, the memory device 150 may take many alternative forms, such as a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus dynamic random access memory (RDRAM), a NAND flash memory, a vertical NAND flash memory, a NOR flash memory device, a resistive RAM (RRAM), a phase-change memory (PRAM), a magnetoresistive RAM (MRAM), a ferroelectric RAM (FRAM), or a spin transfer torque RAM (STT-RAM).

According to an embodiment, the memory device 150 may be implemented as a three-dimensional array structure. The present disclosure may be applied not only to a flash memory device in which a charge storage layer is configured as a conductive floating gate (FG), but also to a charge trap flash (CTF) in which the charge storage layer is configured as an insulating layer.

As an example, the memory device 150 according to an embodiment of the present disclosure includes at least partially a NAND flash memory having nonvolatile characteristics. That is, the memory device 150 may include at least a part of a nonvolatile memory area therein.

Specifically, the nonvolatile memory area included in the memory device 150 may include a plurality of memory blocks 152, 154, and 156. The memory block may be a unit for performing an erase operation for erasing data stored in the memory device 150. That is, data stored in substantially the same memory block may be simultaneously erased.

The nonvolatile memory area included in the memory device 150 may include a plurality of planes each including the plurality of memory blocks 152, 154, and 156. The nonvolatile memory area included in the memory device 150 may include a plurality of memory dies each including a plurality of planes. Each of the plurality of planes may be an independently operable area. That is, each of the plurality of planes may independently perform any of a write operation, a read operation, and an erase operation.

Each of the plurality of memory blocks 152, 154, and 156 may include a plurality of word lines. Each of the plurality of word lines may logically include at least one page. That is, it may be divided into a single level cell (SLC) and a multilevel cell (MLC) according to the number of bits that can be stored or expressed in one memory cell. The page may be a unit for storing data in the memory device 150 or reading data stored in the memory device 150. That is, a physical address provided by the controller 130 to the memory device 150 during a write operation or a read operation may be an address for identifying a specific page.

According to an embodiment, when a single-level cell is included, each of the plurality of word lines may logically include one page. According to another embodiment, when a 2-bit multilevel cell is included, each of the plurality of word lines may logically include two pages. According to further another embodiment, when a triple level cell (TLC), which is a 3-bit multilevel cell, is included, each of the plurality of word lines may logically include three pages, According to yet another embodiment, when a quadruple level cell (QLC), which is a 4-bit multilevel cell, is included, each of the plurality of word lines may logically include four pages.

The operating speeds and the operation methods of the memory system 110 and the controller 130 and the memory device 150 included in the memory system 110 may be changed according to a plurality of performance classes suggested by a manufacturing company. In such a case, the manufacturing company may generate a list CLASS LIST of the plurality of performance classes and performance information CLASS TABLE<1:N>, in which a group of performance parameter values for each of the plurality of performance classes are included in the form of a table, in the process of manufacturing the memory system 110, store the list CLASS LIST and the performance information CLASS TABLE<1:N> in the memory device 150, and ship the memory system 110.

Particularly, in the present disclosure, the memory system 110 may store the performance information CLASS TABLE<1:N> and the list CLASS LIST in a non-volatile storage area. For example, when the memory device 150 is a hybrid memory device including both a volatile memory area and a nonvolatile memory area, the memory system 110 may store the performance information CLASS TABLE<1:N> and the list CLASS LIST in the nonvolatile memory area. According to the embodiment, as illustrated in the drawing, the performance information CLASS TABLE<1:N> and the list CLASS LIST may be stored in the third memory block 156 of the plurality of memory blocks 152, 154, and 156 included in the memory device 150, In the illustrated drawing, the third memory block 156 may be the non-volatile memory area, and unlike the illustrated example, another memory block may be a non-volatile storage area. According to another embodiment, unlike the drawings, a non-volatile storage area may be included in the controller 130, and in such a case, the performance information CLASS TABLE<1: N> and the list CLASS LIST may be stored in the non-volatile storage area in the controller 130.

In the present disclosure, the controller 130 may transmit the list CLASS LIST stored in the non-volatile storage area of the memory device 150 to the host 102 in an entry section of a set operation mode that can be entered when the memory system 110 is shipped and used in mounting, search for the performance information CLASS TABLE<1:N> stored in the non-volatile storage area of the memory device 150 according to a performance selection command SEL_CMD received from the host 102 in response to the transmission, and select performance parameter values included in the performance information CLASS TABLE<one of 1:N> corresponding to one of the plurality of performance classes. Furthermore, in the present disclosure, the controller 130 may operate at an operating speed and in an operation method determined by applying the performance parameter values included in the performance information CLASS TABLE<one of 1:N> corresponding to a performance class in an escape section of the set operation mode.

That is, in the present disclosure, the controller 130 may receive one of the plurality of performance classes selected from the host 102, the selected performance class being applied in a current state by using the list CLASS LIST stored in the non-volatile storage area of the memory device 150. Furthermore, in the present disclosure, the controller 130 may search for the performance information CLASS TABLE<one of 1:N> corresponding to the performance class selected from the host 102 among the performance information CLASS TABLE<1:N> stored in the non-volatile storage area of the memory device 150, and adjust an operating speed and an operation method by applying, to an internal operation, the performance parameter values included in the performance information CLASS TABLE<one of 1:N> corresponding to the selected performance class.

More specifically, the controller 130 may include a host interface 132, a processor 134, an error correction code (ECC) 138, a memory interface 142, a memory 144, and a class selector 230.

The host 102 and the memory system 110 each may include a controller or an interface for transmitting and receiving signals, data, and the like, in accordance with one or more predetermined protocols. For example, the host interface 132 in the memory system 110 may include an apparatus capable of transmitting signals, data, and the like to the host 102 or receiving signals, data, and the like from the host 102.

The host interface 132 included in the controller 130 may receive signals, commands (or requests), and/or data input from the host 102 via a bus. For example, the host 102 and the memory system 110 may use a predetermined set of rules or procedures for data communication or a preset interface to transmit and receive data therebetween.

Examples of communication standards or interfaces used to transmit/receive data may include various form factors such as 2.5-inch form factor, 1.8-inch form factor, MO-297, MO-300, M.2, and EDSFF (Enterprise and Data Center SSD Form Factor) and various communication standards or interfaces such as USB (Universal Serial Bus), MMC (Mufti-Media Card), DATA (Parallel Advanced Technology Attachment), SCSI (Small Computer System Interface), ESDI (Enhanced Small Disk Interface), IDE (Integrated Drive Electronics), PCIe (Peripheral Component Interconnect Express), SAS (Serial-attached SCSI), SATA (Serial Advanced Technology Attachment), and MIPI (Mobile Industry Processor Interface).

According to an embodiment, the host interface 132 is a type of layer for exchanging data with the host 102 and is implemented with, or driven by, firmware called a host interface layer (HIL). According to an embodiment, the host interface 132 can include a command queue.

The Integrated Drive Electronics (IDE) or Advanced Technology Attachment (ATA) may be used as one of the interfaces for transmitting and receiving data and, for example, may use a cable including 40 wires connected in parallel to support data transmission and data reception between the host 102 and the memory system 110, When a plurality of memory systems 110 are connected to a single host 102, the plurality of memory systems 110 may be divided into a master and a slave by using a position or a dip switch to which the plurality of memory systems 110 are connected. The memory system 110 set as the master may be used as a main memory device. The IDE (ATA) may include, for example, Fast-ATA, ATAPI, or Enhanced IDE (EIDE).

A Serial Advanced Technology Attachment (SATA) interface is a type of serial data communication interface that is compatible with various ATA standards of parallel data communication interfaces which are used by Integrated Drive Electronics (IDE) devices. The 40 wires in the IDE interface can be reduced to six wires in the SATA interface. For example, 40 parallel signals for the IDE can be converted into 6 serial signals for the SATA interface. The SATA interface has been widely used because of its faster data transmission and reception rate and its less resource consumption in the host 102 used for the data transmission and reception. The SATA interface may connect up to 30 external devices to a single transceiver included in the host 102, In addition, the SATA interface can support hot plugging that allows an external device to be attached to or detached from the host 102, even while data communication between the host 102 and another device is being executed, Thus, the memory system 110 can be connected or disconnected as an additional device, like a device supported by a universal serial bus (USB) even when the host 102 is powered on. For example, in the host 102 having an eSATA port, the memory system 110 may be freely attached to or detached from the host 102 like an external hard disk.

Small Computer System Interface (SCSI) is a type of serial data communication interface used for connecting a computer or a server with other peripheral devices. The SCSI can provide a high transmission speed, as compared with other interfaces such as IDE and SATA, In the SCSI, the host 102 and at least one peripheral device (e.g., memory system 110) are connected in series, but data transmission and reception between the host 102 and each peripheral device may be performed through a parallel data communication. In the SCSI, it is easy to connect or disconnect a device such as the memory system 110 to or from the host 102. The SCSI can support connections of 15 other devices to a single transceiver included in host 102.

Serial Attached SCSI (SAS) can be understood as a serial data communication version of the SCSI, In the SAS, the host 102 and a plurality of peripheral devices are connected in series, and data transmission and reception between the host 102 and each peripheral device may be performed in a serial data communication scheme. The SAS can support connection between the host 102 and the peripheral device through a serial cable instead of a parallel cable, to easily manage equipment using the SAS and enhance or improve operational reliability and communication performance. The SAS may support connections of eight external devices to a single transceiver included in the host 102.

The Non-volatile memory express (NVMe) is a type of interface based at least on a Peripheral Component Interconnect Express (PCIe) designed to increase performance and design flexibility of the host 102, servers, computing devices, and the like equipped with the non-volatile memory system 110. The PCIe can use a slot or a specific cable for connecting a computing device (e.g., host 102) and a peripheral device (e.g., memory system 110). For example, the PCIe can use a plurality of pins (e.g., 18 pins, 32 pins, 49 pins, or 82 pins) and at least one wire (e.g., x1, x4, x8, or x16) to achieve high speed data communication over several hundred MB per second (e.g., 250 MB/s, 500 MB/s, 984.6250 MB/s, or 1969 MB/s). According to an embodiment, the PCIe scheme may achieve bandwidths of tens to hundreds of Giga bits per second. The NVMe can support an operation speed of the non-volatile memory system 110, such as an SSD, that is faster than a hard disk.

According to an embodiment, the host 102 and the memory system 110 may be connected through a universal serial bus (USB). The Universal Serial Bus (USB) is a type of scalable, hot-pluggable plug-and-play serial interface that can provide cost-effective standard connectivity between the host 102 and peripheral devices such as a keyboard, a mouse, a joystick, a printer, a scanner, a storage device, a modem, a video camera, and the like, A plurality of peripheral devices such as the memory system 110 may be coupled to a single transceiver included in the host 102.

The class selector 230 may adjust the operating speeds and the operation methods of the memory system 110 and the controller 130 and the memory device 150 included in the memory system 110 under the control of the processor 134.

The ECC 138 can correct error bits of the data to be processed in (e.g., outputted from) the memory device 150, which may include an ECC encoder and an ECC decoder. Here, the ECC encoder can perform error correction encoding of data to be programmed in the memory device 150 to generate encoded data into which a parity bit is added and store the encoded data in memory device 150. The ECC decoder can detect and correct errors contained in a data read from the memory device 150 when the controller 130 reads the data stored in the memory device 150. For example, after performing error correction decoding on the data read from the memory device 150, the ECC 138 can determine whether the error correction decoding has succeeded and output an instruction signal (e.g., a correction success signal or a correction fail signal). The ECC 138 can use the parity bit which is generated during the ECC encoding process, for correcting the error bit of the read data. When the number of the error bits is greater than or equal to a threshold number of correctable error bits, the ECC 138 might not correct error bits but instead may output an error correction fail signal indicating failure in correcting the error bits, Particularly, in the present disclosure, an operating speed of the ECC 138, that is, a speed of an operation of detecting and correcting an error included in data read from the memory device 150, may be adjusted according to the performance class selected by the class selector 230.

The ECC 138 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), and so on. The ECC 138 may include any and all circuits, modules, systems or devices for performing the error correction operation based on at least one of the above described codes.

The memory interface 142 may serve as an interface for handling commands and data transferred between the controller 130 and the memory device 150, to allow the controller 130 to control the memory device 150 in response to a request delivered from the host 102. The memory interface 142 may generate a control signal for the memory device 150 and may process data entered into or outputted from the memory device 150 under the control of the processor 134 when the memory device 150 is a flash memory and, in particular, when the memory device 150 is a NAND flash memory. The memory interface 142 can provide an interface for handling commands and data between the controller 130 and the memory device 150, for example, operations of NAND flash interface, in particular, operations between the controller 130 and the memory device 150. In accordance with an embodiment, the memory interface 142 can be implemented through firmware called a Flash Interface Layer (FIL) as a component for exchanging data with the memory device 150.

The memory interface 142 and the memory device 150 may exchange data through a plurality of physically connected channels. Particularly, in the present disclosure, the memory interface 142 may adjust the operating speed and operation method of the memory device 150 according to the performance class selected by the class selector 230. According to an embodiment, the memory interface 142 may adjust the operating speed of the memory device 150 by changing the frequency of a clock signal used inside the memory device 150. According to another embodiment, the memory interface 142 may adjust the operating speed of the memory device 150 by changing the size of data per time that can be read from the memory device 150, that is, a megatransfer per second (MTs). According to an embodiment, the memory interface 142 may adjust the operation method of the memory device 150 by changing the number of channels that are simultaneously enabled among the plurality of channels physically connected between the memory interface 142 and the memory device 150. In such a case, changing the number of channels that are simultaneously enabled may mean changing the number of interleavings of data that can be transmitted through the enabled channels.

The memory 144 may support operations performed by the memory system 110 and the controller 130. The memory 144 may store temporary or transactional data which occurred or was delivered for operations in the memory system 110 and the controller 130. The controller 130 may control the memory device 150 in response to a request from the host 102, The controller 130 may deliver data read from the memory device 150 into the host 102. The controller 130 may store data entered through the host 102 within the memory device 150. The memory 144 may be used to store data for the controller 130 and the memory device 150 in order to perform operations such as read operations, program/write operations or an erase operation.

The memory 144 may be realized by a volatile memory. For example, the memory 144 may be realized by a static random access memory (SRAM) or a dynamic random access memory (DRAM), The memory 144 may exist inside the controller 130 as illustrated in the drawing. Alternatively, the memory 144 may exist outside the controller 130 unlike the illustration of the drawing. In this case, the memory 144 may be realized as an external volatile memory to and from which data is inputted and outputted from, and to the controller 130 through a separate memory interface.

As described above, the memory 144 may store data required to perform operations such as data writing and reading between the host 102 and the memory device 150, data when the operations such as data writing and reading are performed, and the performance information CLASS TABLE<one of 1:N> corresponding to the performance class selected by the processor 134 among the plurality of performance information CLASS TABLE<1:N> corresponding to the plurality of performance classes. For such data storage, the memory 144 includes a data memory, a write buffer/cache, a read buffer/cache, a data buffer/cache, a map buffer/cache, and the like.

The processor 134 controls the entire operations of the memory system 110. In particular, the processor 134 controls a program operation or a read operation for the memory device 150, in response to a write request or a read request from the host 102. Particularly, in the present disclosure, the processor 134 may transmit the list CLASS LIST to the host 102 through the host interface 132 in the entry section of the set operation mode, search for the plurality of performance information CLASS TABLE<1:N> stored in the memory device 150 according to a performance selection command SEL_CMD received from the host 102 through the host interface 132, and select the performance information CLASS TABLE<one of 1:N> corresponding to the selected performance class. Furthermore, in the present disclosure, the processor 134 may apply the value of the performance information CLASS TABLE<1:N> corresponding to the performance class selected in the entry section of the set operation mode to the class selector 230 in the escape section of the set operation mode, thereby adjusting the operating speeds of and the operation methods of the memory system 110, the controller 130, and the memory device 150. In such a case, the operating speed of the processor 134, that is, a speed of performing the operation of the processor 134 to be described below, may be adjusted according to the performance class selected by the class selector 230.

The processor 134 drives firmware which is referred to as a flash translation layer (FTL), to control general operations of the memory system 110. The processor 134 may be realized by a microprocessor or a central processing unit (CPU).

For instance, the controller 130 performs an operation requested from the host 102, in the memory device 150. That is, the controller 130 performs a command operation corresponding to a command received from the host 102, with the memory device 150, through the processor 134 embodied by a microprocessor or a central processing unit (CPU), The controller 130 may perform a foreground operation as a command operation corresponding to a command received from the host 102. For example, the controller 130 may perform a program operation corresponding to a write command, a read operation corresponding to a read command, and an erase operation corresponding to an erase command.

The controller 130 may also perform a background operation for the memory device 150, through the processor 134 embodied by a microprocessor or a central processing unit (CPU). The background operation for the memory device 150 may include an operation of copying data stored in a memory block among the memory blocks 152, 154 and 156 of the memory device 150 to another memory block, for example, a garbage collection (GC) operation. The background operation may include an operation of swapping data between one or more of the memory blocks 152, 154 and 156 of the memory device 150, for example, a wear leveling (WL) operation and a read reclaim (RR) operation. The background operation may include an operation of storing map data retrieved from the controller 130 in the memory blocks 152, 154 and 156 of the memory device 150, for example, a map flush operation. The background operation may include a bad management operation for the memory device 150, which may include checking for and processing a bad block among the plurality of memory blocks 152, 154 and 156 in the memory device 150.

Moreover, a test operation may be performed on the memory system 110 and the controller 130 and the memory device 150 included in the memory system 110 at the time when the manufacturing company produces the memory system 110. A plurality of performance classes optimized for the memory system 110 and the controller 130 and the memory device 150 included in the memory system 110 may be classified according to the result of the test operation.

According to an embodiment, the plurality of performance classes may include a performance class capable of substantially maintaining maximum performance at a level that the life expectancy of the memory system 110, the controller 130 and the memory device 150 included in the memory system 110 is reduced to a minimum, a performance class required to substantially maintain the life expectancy of the memory system 110, the controller 130 and the memory device 150 included in the memory system 110 without reducing the life expectancy, a performance class required to substantially maintain the amount of power used by the memory system 110, the controller 130 and the memory device 150 included in the memory system 110 to a preset value, a performance class required to substantially minimize the amount of power used by the memory system 110, the controller 130 and the memory device 150 included in the memory system 110, a performance class in which a data processing amount and a used power amount of the memory system 110, the controller 130 and the memory device 150 included in the memory system 110 are adjusted according to a predetermined ratio, and the like.

In such a case, in order for the memory system 110 and the controller 130 and the memory device 150 included in the memory system 110 to operate at a selected one of the plurality of performance classes, performance parameter values for setting the operations of the memory system 110, the controller 130 and the memory device 150 included in the memory system 110 need to be adjusted to values corresponding to the selected performance class.

According to an embodiment, performance parameters for setting the operations of the memory system 110, the controller 130 and the memory device 150 included in the memory system 110 may include a parameter for setting the operating speed of the memory device 150, a parameter for setting the number of channels activated between the memory device 150 and the controller 130, a parameter for adjusting the operating speed of the ECC included in the controller 130, a parameter for adjusting the operating speed of the processor 134 included in the controller 130, and the like.

When adjusting each of the performance parameter values to have a certain value, the manufacturing company may check in advance a performance class, at which the memory system 110 and the controller 130 and the memory device 150 included in the memory system 110 operate, through a test, and classify the plurality of performance classes according to the check result.

Accordingly, classifying the plurality of performance classes by the manufacturing company means generating, through a test, performance information CLASS TABLE<1:N> in which a group of performance parameter values for each of the plurality of performance classes are included in the form of a table. N is a natural number equal to or greater than 2 and may mean a type of performance class.

Since a group of the performance parameter values for each of the plurality of performance classes is included in the performance information CLASS TABLE<1:N> in the form of a table, the size of the performance information CLASS TABLE<1:N> may be very large. Accordingly, in the present disclosure, the list CLASS LIST of the plurality of performance classes may be further generated separately from the performance information CLASS TABLE<1:N>. Since the list CLASS LIST is information for distinguishing the plurality of performance classes, it may have a very small size compared to the performance information CLASS TABLE<1:N>. For example, when N, which indicates the type of the plurality of performance classes, is 4, the list CLASS LIST may have a size of 2 bits for distinguishing N.

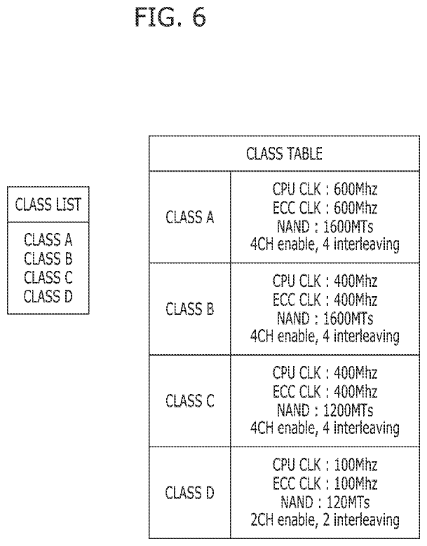

Referring to FIG. 6 together with FIG. 1, it can be seen in what form the performance information CLASS TABLE<1:N> and the list CLASS LIST are generated.

First, it is illustrated as an example that the plurality of performance classes are classified into four types CLASS A, CLASS B, CLASS C, and CLASS D.

In such a case, the list CLASS LIST may include information of the performance classes CLASS A, CLASS B, CLASS C, and CLASS D.

It can be seen that in the performance information CLASS TABLE<1:N>, a group of performance parameter values is included in the table for each of the performance classes CLASS A, CLASS B, CLASS C, and CLASS D.

Specifically, a clock CPU CLK for adjusting the operating speed of the processor 134 included in the controller 130 has a frequency of 600 MHz, a clock ECC CLK for adjusting the operating speed of the ECC 138 included in the controller 130 has a frequency of 600 MHz, the memory device 150 substantially maintains an operating speed of 1,600 MTs (mega transfers per second), and all four channels physically connected between the memory interface 142 and the memory device 150 are enabled (4CH enable), so that performance parameter values, which are set to support an operation method enabling four data interleaving operations, may be grouped for the performance class of CLASS A.

Furthermore, the clock CPU CLK for adjusting the operating speed of the processor 134 included in the controller 130 has a frequency of 400 MHz, the clock ECC CLK for adjusting the operating speed of the ECC 138 included in the controller 130 has a frequency of 400 MHz, the memory device 150 substantially maintains an operating speed of 1,600 MTs (mega transfers per second), and all the four channels physically connected between the memory interface 142 and the memory device 150 are enabled (4CH enable), so that performance parameter values, which are set to support an operation method enabling four data interleaving operations, may be grouped for the performance class of CLASS B.

Furthermore, the clock CPU CLK for adjusting the operating speed of the processor 134 included in the controller 130 has a frequency of 400 MHz, the clock ECC CLK for adjusting the operating speed of the ECC 138 included in the controller 130 has a frequency of 400 MHz, the memory device 150 substantially maintains an operating speed of 1,200 MTs (mega transfers per second), and all four channels physically connected between the memory interface 142 and the memory device 150 are enabled (4CH enable), so that performance parameter values, which are set to support an operation method enabling four data interleaving operations, may be grouped for the performance class of CLASS C.

Furthermore, the clock CPU CLK for adjusting the operating speed of the processor 134 included in the controller 130 has a frequency of 100 MHz, the clock ECC CLK for adjusting the operating speed of the ECC 138 included in the controller 130 has a frequency of 100 MHz, the memory device 150 substantially maintains an operating speed of 120 MTs (mega transfers per second), and only two of the four channels physically connected between the memory interface 142 and the memory device 150 are enabled (2CH enable), so that performance parameter values, which are set to support an operation method enabling two data interleaving operations, may be grouped for the performance class of CLASS D.

As described above, the manufacturing company may perform a test operation on the memory system 110 and the controller 130 and the memory device 150 included in the memory system 110, generate the list CLASS LIST for distinguishing the plurality of performance classes and the performance information CLASS TABLE<1:N> in which a group of the performance parameter values for each of the plurality of performance classes are included in the form of a table, store the generated list CLASS LIST and performance information CLASS TABLE<1:N> in a specific storage area included in the memory device 150 and having nonvolatile characteristics, and then ship the memory system 110. That is, when the memory system 110 according to an embodiment of the present disclosure is mounted for use, the memory system 110 may be in a state in which the list CLASS LIST and the performance information CLASS TABLE<1:N> are stored in the specific storage area included in the memory device 150 and have nonvolatile characteristics.

For reference, the test operation may be performed through separate test equipment physically separated from the memory system 110, the controller 130 and the memory device 150 included in the memory system 110.

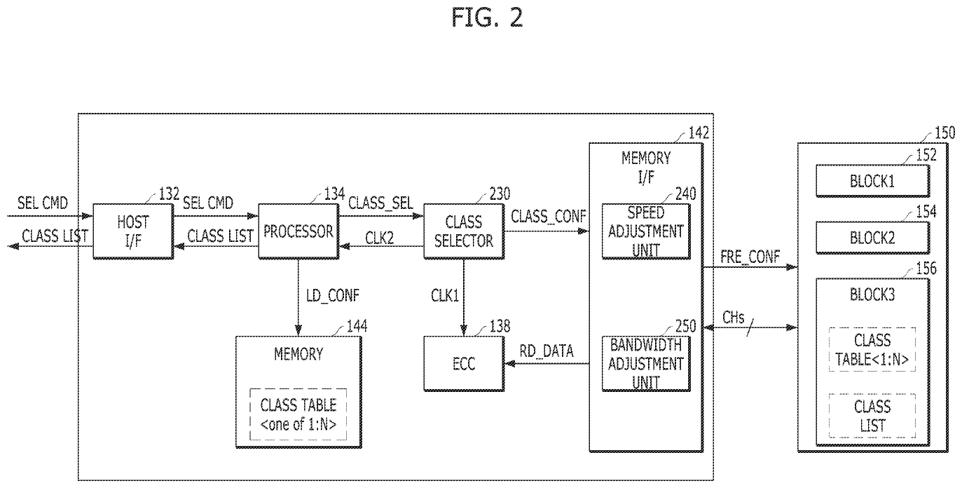

FIG. 2 is a diagram for describing the operations of the components included in the memory system 110 illustrated in FIG. 1 according to an embodiment of the present disclosure.

Referring to FIG. 1 and FIG. 2, the memory system 110 according to an embodiment of the present disclosure may include the controller 130 and the memory device 150. The operating speeds and the operation methods of the memory system 110, the controller 130 and the memory device 150 included in the memory system 110 may be changed according to the plurality of performance classes suggested by the manufacturing company.

Particularly, the manufacturing company may generate the list CLASS LIST of the plurality of performance classes and the performance information CLASS TABLE<1:N>, in which a group of the performance parameter values for each of the plurality of performance classes are included in the form of a table, in the process of manufacturing the memory system 110, store the list CLASS LIST and the performance information CLASS TABLE<1:N> in the memory device 150, and ship the memory system 110. That is, the values of the list CLASS LIST and the performance information CLASS TABLE<1:N> may be determined by the manufacturing company in the process of producing the memory system 110.

Specifically, the memory device 150 may include at least partially the nonvolatile memory area therein, and the performance information CLASS TABLE<1:N> and the list CLASS LIST may be stored in the nonvolatile memory area.

The controller 130 may transmit the list CLASS LIST stored in the non-volatile storage area of the memory device 150 to the host 102 in the entry section of the set operation mode that can be entered when the memory system 110 is shipped and mounted for use, search for the performance information CLASS TABLE<1:N> stored in the non-volatile storage area of the memory device 150 according to the performance selection command SEL_CMD received from the host 102 in response to the transmission, and select performance parameter values included in the performance information CLASS TABLE<one of 1:N> corresponding to the selected performance class among the plurality of performance classes. Furthermore, the controller 130 may operate at an operating speed and in an operation method determined by applying the performance parameter values included in the performance information CLASS TABLE<one of 1:N> corresponding to a selected performance class in the escape section of the set operation mode.

The controller 130 may include the host interface 132, the processor 134, the ECC 138, the memory interface 142, the memory 144, and the class selector 230.

The class selector 230 may adjust the operating speeds and the operation methods of the memory system 110, the controller 130 and the memory device 150 included in the memory system 110 under the control of the processor 134. To this end, the class selector 230 may adjust frequencies of a first dock signal CLK1 and a second clock signal CLK2 in response to a performance selection signal CLASS_SEL. Furthermore, the class selector 230 may change the value of a performance adjustment signal CLASS_CONF in response to the performance selection signal CLASS_SEL.

The operating speed of the ECC 138, that is, the speed of an operation of detecting and correcting an error included in data RD_DATA read from the memory device 150, may be adjusted according to a performance class selected by the class selector 230, To this end, the ECC 138 may perform an error correction operation on the data RD_DATA read from the memory device 150, in response to the first clock signal CLK1 whose toggling frequency is adjusted by the class selector 230. That is, the ECC 138 may perform the error correction operation on the data RD_DATA read from the memory device 150, at a speed corresponding to the frequency of the first clock signal CLK1.

The memory interface 142 may adjust the operating speed and the operation method of the memory device 150 according to the performance class selected by the class selector 230. According to an embodiment, the memory interface 142 may adjust the operating speed of the memory device 150 by changing the frequency of a dock signal used inside the memory device 150. According to another embodiment, the memory interface 142 may adjust the operating speed of the memory device 150 by changing the size of data per time that can be read from the memory device 150, that is, the megatransfer per second (MTs). According to an embodiment, the memory interface 142 may control the operation method of the memory device 150 by changing the number of channels that are simultaneously enabled among the plurality of channels physically connected between the memory interface 142 and the memory device 150. In such a case, changing the number of channels that are simultaneously enabled may mean changing the number of interleaving operations of data that can be transmitted through the enabled channels. To this end, the memory interface 142 may change the value of a signal FRE_CONF for controlling the operating speed and the operation method of the memory device 150 in response to the performance adjustment signal CLASS_CONF whose value may be changed by the class selector 230, transmit the signal FRE_CONF to the memory device 150, and select and enable only a channel to be used among the plurality of channels CHs physically connected between the memory interface 142 and the memory device 150. According to an embodiment, the memory device 150 may change the frequency of a clock signal used inside to adjust the operating speed in response to the signal FRE_CONF transmitted from the memory interface 142. According to another embodiment, the memory device 150 may change the size of data per time that can be read from the memory blocks 152, 154 and 156, that is, the megatransfer per second (MIs), to adjust the operating speed in response to the signal FRE_CONF transmitted from the memory interface 142.

More specifically, the memory interface 142 may include a speed adjustment unit 240 and a bandwidth adjustment unit 250. The speed adjustment unit 240 and the bandwidth adjustment unit 250 include all circuits, systems, software, firmware and devices necessary for their respective operations and functions.

The speed adjustment unit 240 may generate an internal command for adjusting the operating frequency of the memory device 150 in response to the performance adjustment signal CLASS_CONF whose value may be changed by the class selector 230, and transmit the generated internal command to the memory device 150.

The bandwidth adjustment unit 250 may adjust the number of channels that are simultaneously enabled among the plurality of channels physically connected between the memory interface 142 and the memory device 150, in response to the performance adjustment signal CLASS_CONF whose value may be changed by the class selector 230.

In the above description, only an operation, in which the plurality of channels are physically connected between the memory interface 142 and the memory device 150, and the number of interleavings of data is adjusted by adjusting the number of channels that are simultaneously enabled among the plurality of channels, has been disclosed as an example. However, this is only one example, and a channel may include a plurality of ways, and a method of adjusting the number of interleavings of data by adjusting ways that are simultaneously enabled among the plurality of ways may also be possible.

Then, the processor 134 may transmit the list CLASS LIST to the host 102 through the host interface 132 in the entry section of the set operation mode, search for the plurality of performance information CLASS TABLE<1:N> stored in the memory device 150 according to the performance selection command SEL_CMD received from the host 102 through the host interface 132, and select the performance information CLASS TABLE<one of 1:N> corresponding to the selected performance class. Furthermore, in the present disclosure, the processor 134 may apply the value of the performance information CLASS TABLE<1:N> corresponding to the performance class selected in the entry section of the set operation mode to the class selector 230 in the escape section of the set operation mode, thereby adjusting the operating speeds of and the operation methods of the memory system 110, the controller 130, and the memory device 150. In such a case, the operating speed of the processor 134 may be adjusted according to the performance class selected by the class selector 230. To this end, the processor 134 may control the operation of the class selector 230 by determining the value of the performance selection signal CLASS_SEL with reference to the performance parameter values included in the performance information CLASS TABLE<one of 1:N> corresponding to the performance class selected in response to the performance selection command SEL_CMD received from the host 102 in the entry section of the set operation mode. Furthermore, the processor 134 may operate at a speed corresponding to the frequency of the second clock signal CLK2 generated by the class selector 230.

After the processor 134 searches for the plurality of performance information CLASS TABLE<1:N> stored in the memory device 150 according to the performance selection command SEL_CMD received from the host 102 in the entry section of the set operation mode and selects the performance information CLASS TABLE<one of 1:N> corresponding to the selected performance class, the memory 144 may store the performance parameter values included in the selected performance information CLASS TABLE<one of 1:N>. In such a case, all operations of the memory 144 may be controlled by a control signal LD_CONF transmitted from the processor 134. That is, the memory 144 may store, update and delete data therein in response to a control signal LD_CONF transmitted from the processor 134. According to an embodiment, the memory 144 may store the performance parameter values included in the selected performance Information CLASS TABLE<one of 1:N> in response to a control signal LD_CONF transmitted from the processor 134.

The performance parameter values included in the performance information CLASS TABLE<one of 1:N>, which are selected by the processor 134, may be stored in the memory 144 by the processor 134 in the entry section of the set operation mode, and may be deleted from the memory 144 by the processor 134 after the class selector 230 adjusts the frequencies of the first dock signal CLK1 and the second dock signal CLK2 and the value of the performance adjustment signal CLASS_CONF according to a result of the processor 134 determining the value of the performance selection signal CLASS_SEL in the escape section of the set operation mode.

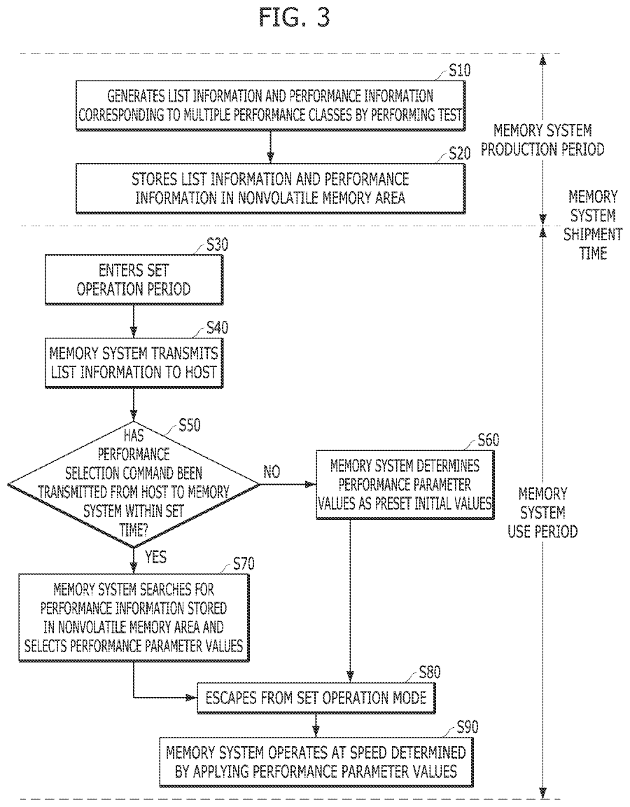

FIG. 3 to FIG. 5 are flowcharts for describing the operation of the memory system 110 according to an embodiment of the present disclosure illustrated in FIG. 1 and FIG. 2.

Referring to FIG. 3, the operation of the memory system 110 according to an embodiment of the present disclosure may be roughly divided into two periods. That is, the operation of the memory system 110 according to an embodiment of the present disclosure may include a production period S10 and S20 of the memory system 110 and a use period S30, S40, S50, S60, S70, S80, and S90 of the memory system 110.

The production period S10 and S20 of the memory system 110 may indicate a period before the manufacturing company produces and ships the memory system 110.

The use period S30, S40, S50, S60, S70, S80, and S90 of the memory system 110 may indicate a period in which the manufacturing company ships the memory system 110 and then the memory system 110 is mounted into a data processing system connected to the host 102 and is then used by a user.

Specifically, in the production period S10 and S20 of the memory system 110, the manufacturing company may perform a test operation on the memory system 110, the controller 130 and the memory device 150 included in the memory system 110. The manufacturing company may classify the plurality of performance classes optimized for the memory system 110, the controller 130 and the memory device 150 included in the memory system 110 according to a result of the test operation, and generate the list CLASS LIST and the performance information CLASS TABLE<1:N> corresponding to the plurality of performance classes (S10).

Then, the manufacturing company may store the list CLASS LIST and the performance information CLASS TABLE<1:N> corresponding to the plurality of performance classes in the nonvolatile memory area included in the memory device 150 of the memory system 110 (S20).

When the list CLASS LIST and the performance information CLASS TABLE<1:N> are stored in the nonvolatile memory area included in the memory device 150 of the memory system 110 through S20, the manufacturing company may ship the memory system 110 to the user.

After the memory system 110 produced through the production period S10 and S20 is shipped to the user, the memory system 110 may be mounted into the data processing system connected to the host 102 and used by the user, That is, it may enter the use period S30, S40, S50, S60, S70, S80, and S90 of the memory system 110.

Specifically, in the use period S30, S40, S50, S60, S70, S80, and S90, the memory system 110 may enter the set operation period (S30). When the memory system 110 does not enter the set operation period, the memory system 110 may perform a normal operation of storing data at the request of the user.

When the memory system 110 enters the set operation period in S30, the controller 130 included in the memory system 110 may load the list CLASS LIST from the nonvolatile memory area of the memory device 150, and transmit the list CLASS LIST to the host 102 (S40). That is, the list CLASS LIST may be transmitted from the memory system 110 to the host 102.

Upon receiving the list CLASS LIST in S40, the host 102 may request the user to select the plurality of performance classes, and when any class is selected by the user, the host 102 may generate the performance selection command SEL_CMD corresponding to the selected performance class and transmit the performance selection command SEL_CMD to the memory system 110.

In such a case, even though the host 102 requests the user to select the plurality of performance classes, there may be no response from the user for a set time. In such a case, the host 102 may not transmit the performance selection command SEL_CMD to the memory system 110 within the set time. Accordingly, the memory system 110 may transmit the list CLASS LIST to the host 102, then check whether the performance selection command SEL_CMD is received from the host 102 within the set time (S50).

When the performance selection command SEL_CMD is not received from the host 102 within the set time in S50 (NO in S50), the controller 130 included in the memory system 110 may not search for the performance information CLASS TABLE<1:N> stored in the non-volatile storage area of the memory device 150, and determine, as preset initial values, the performance parameter values included in the performance information CLASS TABLE<one of 1:N> corresponding to the selected performance class (S60). In such a case, the preset initial values may mean values that may be preset in the process of producing the memory system 110 by the manufacturing company, and may have performance parameter values corresponding to any of the performance information CLASS TABLE<1:N> stored in the non-volatile storage area of the memory device 150, For example, in FIG. 6, performance parameter values corresponding to the performance class of CLASS B may be set as the preset initial values.

When the performance selection command SEL_CMD is received from the host 102 within the set time in S50 (YES in S50), the controller 130 included in the memory system 110 may search for the performance information CLASS TABLE<1:N> stored in the non-volatile storage area of the memory device 150 according to the performance selection command SEL_CMD received from the host 102, and select the performance parameter values included in performance information TO CLASS TABLE<one of 1:N> corresponding to the selected performance class among the plurality of performance classes (S70).

When the performance parameter values included in the performance information CLASS TABLE<one of 1:N> corresponding to the selected performance class are determined as the preset initial values in S60 or the performance parameter values included in the performance information CLASS TABLE<one of 1:N> corresponding to the selected performance class are detected in S70, the controller 130 may escape from the set operation mode (S80).

When escaping from the set operation mode in S80, the controller 130 included in the memory system 110 may operate at an operating speed and in an operation method determined by applying the performance parameter values included in the performance information CLASS TABLE<one of 1:N> corresponding to the selected performance class (S90).

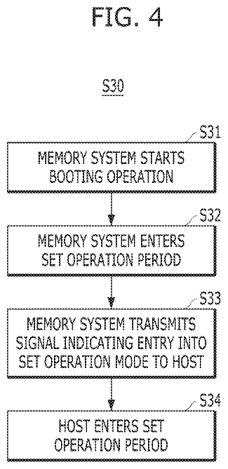

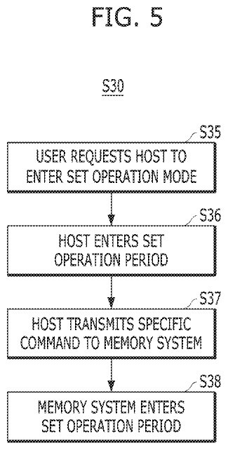

The operation of S30 in which the memory system 110 enters the set operation period may be divided into two cases with reference to FIG. 4 and FIG. 5.

Referring to FIG. 3 and FIG. 4, the memory system 110 may start a booting operation (S31), According to an embodiment, each of the host 102 and the memory system 110 may perform a booting operation in response to the supply of power to both the host 102 and the memory system 110. According to another embodiment, the host 102 may transmit a reboot command to the memory system 110, so that only the memory system 110 may perform a booting operation regardless of the host 102, According to further another embodiment, a plurality of memory systems may be connected to the host 102, and under the control of the host 102, some memory systems may be in a used state, but others may be in an unused state. In such a case, the host 102 may control a specific memory system to be selected and used among the unused memory systems, and in such a case, only a newly used memory system may perform a booting operation.

When the memory system 110 performs the booting operation in S31, the controller 130 included in the memory system 110 may enter a set operation mode by itself (S32).

After the controller 130 included in the memory system 110 enters the set operation mode by itself in S32, the controller 130 may transmit a signal indicating entry into the set operation mode to the host 102 (S33).

When the signal indicating entry into the set operation mode is transmitted from the memory system 110 to the host 102 in S33, the host 102 may enter the set operation mode (S34). In such a case, after entering the set operation mode, the host 102 may predict and prepare that the operation of S40 in which the list CLASS LIST is transmitted from the memory system 110, is to be performed.

Referring to FIG. 3 and FIG. 5, the user, who mounts and uses the data processing system including the host 102 and the memory system 110, may request the host 102 to enter the set operation mode (S35).

When the user requests the host 102 to enter the set operation mode in S35, the host 102 may enter the set operation mode by itself (S36).

After the host 102 enters the set operation mode by itself in S36, the host 102 may generate a specific command and transmit the specific command to the memory system 110 (S37).

When the specific command is transmitted from the host 102 to the memory system 110 in S37, the memory system 110 may enter the set operation mode (S38). After transmitting the specific command, the host 102 may predict and prepare that the operation of S40 in which the list CLASS LIST is transmitted from the memory system 110, is to be performed.

The present disclosure described above is not limited by the aforementioned embodiment and the accompanying drawings, and it will be apparent to those skilled in the art to which the present disclosure pertains that various replacements, modifications, and changes can be made without departing from the technical spirit of the present disclosure and the following claims. Furthermore, the embodiments may be combined to form additional embodiments.

What is claimed is:

1. A memory system comprising:
a memory device configured to store, in a non-volatile storage area included therein, a list of a plurality of performance classes and a table of performance information representing a group of performance parameter values for each of the plurality of performance classes; and
a controller configured to provide the list to an external device according to a first request received from the external device, select one of the plurality of performance classes within the table according to a second request received from the external device, and control an operation of the memory device at an operation speed and in an operation method according to the performance parameter values corresponding to the selected performance class.

2. The memory system of claim 1, wherein the controller comprises:
an internal storage circuit including the non-volatile storage area;
a class selector configured to adjust frequencies of first and second clock signals and change a value of a performance adjustment signal in response to a performance selection signal;
a memory interface configured to adjust an operation speed and an operation method in response to the performance adjustment signal;
an error correction circuit configured to perform, at an operation speed corresponding to the frequency of the first dock signal, an error correction operation on data read from the memory device; and
a processor configured to transmit the list in the non-volatile storage area to the external device according to the first request, select the performance class according to the second request, determine a value of the performance selection signal with reference to the performance parameter values corresponding to the selected performance class, and operate at an operation speed corresponding to the frequency of the second clock signal.

3. The memory system of claim 2, wherein the memory interface comprises:
a speed adjustment unit configured to generate an internal command for adjusting an operating frequency of the memory device according to the performance adjustment signal, and to transmit the internal command to the memory device; and
a bandwidth adjustment unit configured to adjust a number of channels, which are simultaneously enabled among a plurality of channels connected to the memory device, according to the performance adjustment signal.

4. A memory system comprising:
a memory device configured to store, in a non-volatile storage area, a list of a plurality of performance classes and a table of performance information representing a group of performance parameter values for each of the plurality of performance classes; and
a controller configured to provide the list to an external device in an entry section of a set operation mode, select one of the plurality of performance classes within the table according to a request received from the external device, and control an operation of the memory device at an operation speed and in an operation method according to the performance parameter values corresponding to the selected performance class in an escape section of the set operation mode.

5. A data processing system comprising:
an external device configured to request a user to select one of a plurality of performance classes within a received list; and
a memory system configured to store, in a nonvolatile memory area, the list and a table of performance information representing a group of performance parameter values for each of the plurality of performance classes, transmit the list to the external device, select one of the plurality of performance classes within the table according to the selected performance class, and operate at an operation speed and in an operation method according to the performance parameter values corresponding to the selected performance class.

6. The data processing system of claim 5, wherein the memory system comprises:
a memory device including the nonvolatile memory area; and
a controller configured to transmit the list to the external device in an entry section of a set operation mode, determine the selected performance class within the table according to a performance selection command received from the external device and indicating the selected performance class, and control an operation of the memory device at the speed and in the method according to the performance parameter values corresponding to the selected performance class in an escape section of the set operation mode.

7. The data processing system of claim 6, wherein the controller is further configured to enter the set operation mode during a booting operation, escape the set operation mode after the determining of the selected performance class, and transmit a signal indicating entry/escape into/from the set operation mode to the external device.

8. The data processing system of claim 7,
wherein the external device is further configured to enter/escape from the set operation mode in response to the signal indicating entry/escape into/from the set operation mode,
wherein the external device requests the user to select the performance class in the entry section of the set operation mode, and
wherein the external device is further configured to generate and output the performance selection command corresponding to the performance class selected by the user.

9. The data processing system of claim 6, wherein the controller is further configured to enter the set operation mode in response to a command received from the external device, escape from the set operation mode after the determining of the selected performance class, and transmit a signal indicating escape from the set operation mode to the external device.

10. The data processing system of claim 9,
wherein the external device is further configured to generate the command by a request of the user, transmit the command to the memory system, enter the set operation mode, and escape from the set operation mode in response to the signal received from the memory system and indicating escape from the set operation mode,
wherein the external device requests the user to select one of the plurality of performance classes within the list in the entry section of the set operation mode, and
wherein the external device is further configured to generate and output the performance selection command corresponding to the performance class selected by the user.

11. The data processing system of claim 6,
wherein the controller transmits the list to the external device in the entry section of the set operation mode, and
wherein the controller is further configured to determine the performance parameter values corresponding to the selected performance class as preset initial values without searching for the performance information when the performance selection command is not received for a set time.

12. A method for operating a data processing system including a memory system including a memory device including a non-volatile storage area and an external device for controlling an operation of the memory system at a request of a user, the method comprising:
a test operation of generating a list of a plurality of performance classes through a test and a table of performance information representing a group of performance parameter values for each of the plurality of performance classes to store the list and the table in the non-volatile storage area;
a list transmission operation of providing the list stored in the memory system to the external device after the test operation;
a selection request operation in which the external device requests a user to select one of the plurality of performance classes within the list after the list transmission operation;
a class selection operation in which the memory system selects one of the plurality of performance classes within the table according to the performance class selected by the user; and
an operation control operation in which the memory system controls an operation of the memory device at an operation speed and in an operation method according to the performance parameter values corresponding to the selected performance class.

13. The method of claim 12, wherein the operation control operation comprises:
adjusting a frequency of an internal dock signal in response to a performance selection signal and changing a value of a performance adjustment signal;
adjusting an operating speed and an operation method of the memory device in response to the performance adjustment signal;
performing an error correction operation on data read from the memory device and performing the error correction operation at a speed corresponding to the frequency of the internal dock signal; and
determining a value of the performance selection signal by applying the performance parameter values corresponding to the selected performance class.

14. The method of claim 12,
further comprising:
a first entry operation of entering the memory system and the external device into a set operation mode during a booting operation of the memory system;
a first middle operation of performing the list transmission operation, the selection request operation, and the class selection operation in an entry section of the set operation mode; and
a first escape operation of escaping the memory system and the external device into from the set operation mode after the first middle operation,
wherein the operation control operation is performed after the first escape operation.

15. The method of claim 12,
further comprising:
a second entry operation of allowing the memory system and the external device to enter a set operation mode at the request of the user; and
a second escape operation of allowing the memory system and the external device to escape from the set operation mode after the second entry operation,
wherein the list transmission operation, the selection request operation, and the class selection operation are performed after the second entry operation, and
wherein the operation control operation is performed after the second escape operation.

16. The method of claim 12, further comprising an operation in which, when a performance class is not selected by the user for a set time in the selection request operation, the memory system controls the operation of the memory device at a speed and in a method according to preset performance parameter values.

17. An operating method of a host and a memory system, the operating method comprising:
providing, by the memory system, the host with information of one or more performance classes;
selecting, by the host, one of the performance classes; and
adjusting, by the memory system, performance thereof according to one or more performance parameter values corresponding to the selected performance class.
